(19) United States
(12) Patent Application Publication
(10) Pub. No.: US 2021/0222281 A1
(43) Pub. Date: Jul. 22, 2021

(54) METHOD OF MANUFACTURING MASK, MASK AND EVAPORATION METHOD WITH MASK

(71) Applicant: BOE Technology Group Co., Ltd., Beijing (CN)

(72) Inventors: Haibin Zhu, Beijing (CN); Xue Dong, Beijing (CN); Guangcai Yuan, Beijing (CN); Weijie Wang, Beijing (CN); Fengjie Zhang, Beijing (CN)

(73) Assignee: BOE Technology Group Co., Ltd., Beijing (CN)

(21) Appl. No.: 16/765,330

(22) PCT Filed: Dec. 20, 2019
(86) PCT No.: PCT/CN2019/127116

§ 371 Date: May 19, 2020

(30) Foreign Application Priority Data
Jan. 4, 2019 (CN) 201910008043.7

(51) Int. Cl. C23C 14/04; C23C 14/24

(52) U.S. Cl. CPC C23C 14/042; C23C 14/24

(57) ABSTRACT

Embodiments of the present disclosure provide a method of manufacturing a mask, a mask and an evaporation method with a mask. The method comprises: providing a frame and a mask body; and fixing the mask body to the frame to form the mask in a case where at least one of the mask body and the frame is at a predetermined temperature, such that the mask body is elastically deformed by a predetermined amount by tensioning the mask body by the frame by a thermal deformation at a usage temperature different from the predetermined temperature.

### CROSS-REFERENCE TO RELATED APPLICATION

This application claims priority to Chinese Patent Application No. 201910008043.7, filed with the State Intellectual Property Office of China on Jan. 4, 2019, which is incorporated herein by reference in its entirety.

### TECHNICAL FIELD

Embodiments of the present disclosure relate to the field of display technology, and particularly to a method of manufacturing a mask, a mask and an evaporation method with a mask.

### BACKGROUND

In a manufacturing process of an organic light emitting diode, a fine metal mask (FMM) is usually used as an evaporation mask, and luminescent materials that emit red, green, and blue light respectively are evaporated through apertures in the fine metal mask into corresponding opening regions of an array substrate, thereby forming an organic light emitting diode device.

### SUMMARY

Embodiments of the present disclosure provide a method of manufacturing a mask, the method comprising: providing a frame and a mask body; and fixing the mask body to the frame to form the mask in a case where at least one of the mask body and the frame is at a predetermined temperature, such that the mask body is elastically deformed by a predetermined amount by tensioning the mask body by the frame by a thermal deformation at a usage temperature different from the predetermined temperature.

According to embodiments of the present disclosure, fixing the mask body to the frame to form the mask in the case where the at least one of the mask body and the frame is at the predetermined temperature, comprises: fixing the mask body to the frame in a case where the frame is at the predetermined temperature lower than the usage temperature and the mask body is at the usage temperature; fixing the mask body to the frame in a case where the frame is at the usage temperature and the mask body is at the predetermined temperature higher than the usage temperature; fixing the mask body to the frame in a case where the mask body and the frame are at the predetermined temperature lower than the usage temperature, such that the frame thermally expands more than the mask body at the usage temperature; or fixing the mask body to the frame in a case where the mask body and the frame are at the predetermined temperature higher than the usage temperature, such that the frame thermally contracts less than the mask body at the usage temperature.

According to embodiments of the present disclosure, the usage temperature is a temperature of the mask at which an evaporation is performed with the mask.

According to embodiments of the present disclosure, the mask body has a less coefficient of thermal expansion than the frame, and fixing the mask body to the frame to form the mask in the case where the at least one of the mask body and the frame is at the predetermined temperature, comprises: fixing the mask body to the frame in a case where the mask body and the frame are at the predetermined temperature T₁, such that the frame thermally expands more than the mask body in a case where the mask is at the usage temperature T₂ and the usage temperature T₂ is greater than the predetermined temperature T₁, so that the mask body is elastically deformed by the predetermined amount by tensioning the mask body by the frame by the thermal deformation.

According to embodiments of the present disclosure, the predetermined amount by which the mask body is elastically deformed by tensioning the mask body by the frame by the thermal deformation is calculated by the following formula:

$${T}_{1} = {T}_{2} - \frac{{L}_{d} - {L}_{0}}{{L}_{0}} \times \frac{1}{{CTE}_{f} - {CTE}_{m}}$$

where T₁ is the predetermined temperature of the mask body and frame at which the mask body is fixed to the frame, T₂ is the usage temperature of the mask body and the frame at which an evaporation is performed with the mask body and the frame, L_{d} is a design size of the mask body, L₀ is an actual size of the mask body, CTE_{f} is the coefficient of thermal expansion of the frame, CTEₘ is the coefficient of thermal expansion of the mask body, and L_{d}−L₀ is the predetermined amount by which the mask body is elastically deformed by tensioning the mask body by the frame by the thermal deformation.

According to embodiments of the present disclosure, the mask body has a greater coefficient of thermal expansion than the frame, and fixing the mask body to the frame to form the mask in the case where the at least one of the mask body and the frame is at the predetermined temperature, comprises: fixing the mask body to the frame in a case where the mask body and the frame are at the predetermined temperature T₁, such that the frame thermally contracts less than the mask body in a case where the mask is at the usage temperature T₂ and the usage temperature T₂ is less than the predetermined temperature T₁, so that the mask body is elastically deformed by the predetermined amount by tensioning the mask body by the frame by the thermal deformation.

According to embodiments of the present disclosure, the predetermined amount by which the mask body is elastically deformed by tensioning the mask body by the frame by the thermal deformation is calculated by the following formula:

$${T}_{1} = {T}_{2} + \frac{{L}_{d} - {L}_{0}}{{L}_{0}} \times \frac{1}{{CTE}_{f} - {CTE}_{m}}$$

where T₁ is the predetermined temperature of the mask body and frame at which the mask body is fixed to the frame, T₂ is the usage temperature of the mask body and the frame at which an evaporation is performed with the mask body and the frame, L_{d} is a design size of the mask body, L₀ is an actual size of the mask body, CTE_{f} is the coefficient of thermal expansion of the frame, CTEₘ is the coefficient of thermal expansion of the mask body, and L_{d}−L₀ is the predetermined amount by which the mask body is elastically deformed by tensioning the mask body by the frame by the thermal deformation.

According to embodiments of the present disclosure, the mask body has a greater coefficient of thermal expansion than the frame, and fixing the mask body to the frame to form the mask in the case where the at least one of the mask body and the frame is at the predetermined temperature, comprises: fixing the mask body to the frame in a case where the frame is at the usage temperature T₂, the mask body is at the predetermined temperature T₁ and the usage temperature T₂ is less than the predetermined temperature T₁, such that the mask body contracts and the frame retains unchanged in size in a case where the mask is at the usage temperature T₂, so that the mask body is elastically deformed by the predetermined amount by tensioning the mask body by the frame by the thermal deformation.

According to embodiments of the present disclosure, the mask body has a same coefficient of thermal expansion as the frame, and fixing the mask body to the frame to form the mask in the case where the at least one of the mask body and the frame is at the predetermined temperature, comprises: fixing the mask body to the frame in a case where the mask body is at the predetermined temperature T₁, the frame is at the usage temperature T₂, and the predetermined temperature T₁ is greater than the usage temperature T₂, such that the mask body contracts and the frame retains unchanged in size in a case where the mask is at the usage temperature T₂, so that the mask body is elastically deformed by the predetermined amount by tensioning the mask body by the frame by the thermal deformation.

According to embodiments of the present disclosure, the predetermined amount by which the mask body is elastically deformed by tensioning the mask body by the frame by the thermal deformation is calculated by the following formula:

$${T}_{1} = {T}_{2} + \frac{{L}_{d} - {L}_{0}}{{L}_{0}} \times \frac{1}{{CTE}_{m}}$$

where T₁ is the predetermined temperature of the mask body at which the mask body is fixed to the frame, T₂ is the usage temperature of the mask body and the frame at which an evaporation is performed with the mask body and the frame, L_{d} is a design size of the mask body, L₀ is an actual size of the mask body, CTEₘ is the coefficient of thermal expansion of the mask body, and L_{d}−L₀ is the predetermined amount by which the mask body is elastically deformed by tensioning the mask body by the frame by the thermal deformation.

According to embodiments of the present disclosure, the method further comprises: before fixing the mask body to the frame to form the mask in the case where the at least one of the mask body and the frame is at the predetermined temperature, heating or cooling the at least one of the mask body and the frame to the predetermined temperature; applying an ultraviolet ray curable adhesive to the frame; and placing the mask body onto the frame to which the ultraviolet ray curable adhesive is applied, wherein fixing the mask body to the frame to form the mask in the case where the at least one of the mask body and the frame is at the predetermined temperature, comprises: curing the ultraviolet ray curable adhesive by irradiating the ultraviolet ray curable adhesive with ultraviolet rays to fix the mask body to the frame.

According to embodiments of the present disclosure, the predetermined temperature is different from an ambient temperature.

According to embodiments of the present disclosure, the method further comprises: before fixing the mask body to the frame to form the mask in the case where the at least one of the mask body and the frame is at the predetermined temperature, heating or cooling the at least one of the mask body and the frame to the predetermined temperature.

According to embodiments of the present disclosure, the mask body has a rectangular shape, the frame has a rectangular ring shape, and the mask body is fixed at its four edges to the frame.

According to embodiments of the present disclosure, the mask body has a same coefficient of thermal expansion as the frame, and fixing the mask body to the frame to form the mask in the case where the at least one of the mask body and the frame is at the predetermined temperature, comprises: fixing the mask body to the frame in a case where the mask body is at the usage temperature T₂, the frame is at the predetermined temperature T₁ and the usage temperature T₂ is greater than the predetermined temperature T₁, such that the mask body retains unchanged in size and the frame expands in a case where the mask is at the usage temperature T₂, so that the mask body is elastically deformed by the predetermined amount by tensioning the mask body by the frame by the thermal deformation.

According to embodiments of the present disclosure, the predetermined amount by which the mask body is elastically deformed by tensioning the mask body by the frame by the thermal deformation is calculated by the following formula:

$${T}_{1} = {T}_{2} - \frac{{L}_{d} - {L}_{0}}{{L}_{0}} \times \frac{1}{{CTE}_{f}}$$

where T₁ is the predetermined temperature of the frame at which the mask body is fixed to the frame, T₂ is the usage temperature of the mask body and the frame at which an evaporation is performed with the mask body and the frame, L_{d} is a design size of the mask body, L₀ is an actual size of the mask body, CTE_{f} is the coefficient of thermal expansion of the frame, and L_{d}−L₀ is the predetermined amount by which the mask body is elastically deformed by tensioning the mask body by the frame by the thermal deformation.

According to embodiments of the present disclosure, immediately after fixing the mask body to the frame, a tensile force applied by the frame to the mask body is zero so that an amount by which the mask body is elastically deformed by the frame is zero.

Embodiments of the present disclosure further provide a mask manufactured by the above method, the mask comprising a frame and a mask body fixed to the frame.

According to embodiments of the present disclosure, a material of the mask body is a glass.

Embodiments of the present disclosure further provide an evaporation method with a mask, the method comprising: providing a frame and a mask body; fixing the mask body to the frame to form the mask in a case where at least one of the mask body and the frame is at a predetermined temperature; and performing, with the formed mask, an evaporation at a usage temperature different from the predetermined temperature, such that the mask body is elastically deformed by a predetermined amount by tensioning the mask body by the frame by a thermal deformation.

According to embodiments of the present disclosure, fixing the mask body to the frame to form the mask in the case where the at least one of the mask body and the frame is at the predetermined temperature, comprises: fixing the mask body to the frame in a case where the frame is at the predetermined temperature lower than the usage temperature and the mask body is at the usage temperature; fixing the mask body to the frame in a case where the frame is at the usage temperature and the mask body is at the predetermined temperature higher than the usage temperature; fixing the mask body to the frame in a case where the mask body and the frame are at the predetermined temperature lower than the usage temperature, such that the frame thermally expands more than the mask body at the usage temperature; or fixing the mask body to the frame in a case where the mask body and the frame are at the predetermined temperature higher than the usage temperature, such that the frame thermally contracts less than the mask body at the usage temperature.

### BRIEF DESCRIPTION OF THE DRAWINGS

The drawings described herein are used to provide further understanding of technical solutions in the embodiments of the present disclosure and constitute a part of the description. The technical solutions in the embodiments of the present disclosure are explained by means of the drawings together with the embodiments of the present disclosure but should not be construed as being limited to the drawings.

FIG. 1 is a schematic view showing structures of components for manufacturing a mask in related art;

FIG. 2 is a flow diagram of a method of manufacturing a mask according to an embodiment of the present disclosure;

FIG. 3 is a schematic diagram showing a temperature change in a process of manufacturing a mask according to an example of the embodiment of the present disclosure;

FIG. 4 is a schematic diagram showing a temperature change in a process of manufacturing a mask according to another example of the embodiment of the present disclosure;

FIG. 5 is a schematic view showing components in steps in which a mask body is fixed to a frame, according to an embodiment of the present disclosure;

FIG. 6 is a section view of the frame shown in FIG. 5 according to an embodiment of the present disclosure;

FIG. 7 is a section view of the mask body and the frame, shown in FIG. 5, in a state where they are fixed together according to an embodiment of the present disclosure;

FIG. 8 is a schematic view of the frame, shown in FIG. 5, to which an adhesive is applied according to an example of an embodiment of the present disclosure;

FIG. 9 is a schematic view of the frame, shown in FIG. 5, to which an adhesive is applied according to another example of the embodiment of the present disclosure;

FIG. 10 is a schematic diagram showing a temperature change in a process of manufacturing a mask according to an example of a further embodiment of the present disclosure;

FIG. 11 is a schematic diagram showing a temperature change in a process of manufacturing a mask according to another example of the further embodiment of the present disclosure;

FIG. 12 is a schematic diagram showing a temperature change in a process of manufacturing a mask according to an example of a still further embodiment of the present disclosure; and

FIG. 13 is a schematic diagram showing a temperature change in a process of manufacturing a mask according to another example of the still further embodiment of the present disclosure.

### DETAILED DESCRIPTION

In order that objects, technical solutions and advantages of the present disclosure become more apparent, the embodiments of the present disclosure will be described in detail with reference to the drawings as below. It is to be noted that the embodiments of the present disclosure and the features in the embodiments of the present disclosure may be optionally combined with one another unless they conflict.

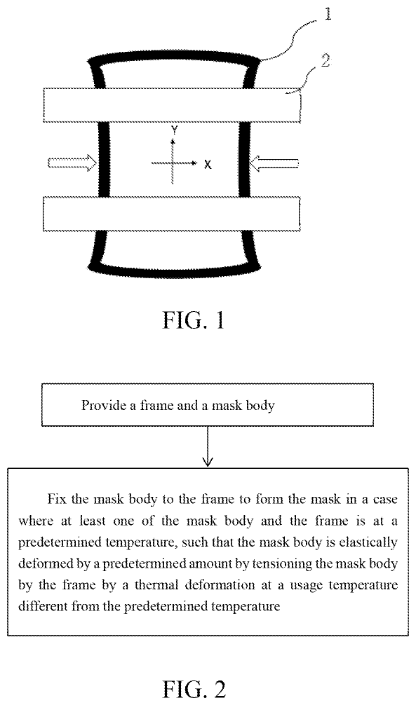

FIG. 1 is a schematic view showing structures of components for manufacturing a mask in related art.

Referring to FIG. 1, in the related art, a material of a fine metal mask is Invar. First, pixel holes are formed in a thin metal sheet by etching to form a mask body 2. Then, a frame 1 is deformed in advance by applying a pair of forces as shown by the hollow arrows to the frame 1. Next, the mask body 2 is flattened by applying a horizontal tensile force and positions of the pixel openings are adjusted. Finally, the mask body 2 is welded to the frame 1. After the forces applied to the frame 1 are removed, the horizontal tensile force applied to the original mask body 2 is replaced with a resilience force of the frame 1 to maintain the position accuracy of the mask body 2 as shown in FIG. 1. However, when the mask is manufactured by this method, the frame 1 can generate the tensile force only along a direction in which the mask body 2 is tensioned (the X direction in FIG. 1), but can generate no tensile force in a direction (the Y direction in FIG. 1) perpendicular to the X direction, so that the mask body will naturally contract in the Y direction, which will easily cause an offset of a pixel position in the Y direction. In addition, when the mask is manufactured in this manner, the tensile force applied by the frame 1 to the mask body is not uniform, which will also easily cause an offset of a pixel position in the X direction.

Although the above metal mask has a low coefficient of thermal expansion, a rise in a temperature of the mask in an evaporation chamber will also produce a certain amount of deformation and thus cause a positional deviation. In addition, this method is not suitable for a mask of a material other than a metal mask, such as a glass-based mask which has characteristics of high hardness and brittleness.

FIG. 2 is a flow diagram of a method of manufacturing a mask according to an embodiment of the present disclosure.

As shown in FIG. 2, Embodiments of the present disclosure provide a method of manufacturing a mask. The method comprises: providing a frame and a mask body; and fixing the mask body to the frame to form the mask in a case where at least one of the mask body and the frame is at a predetermined temperature, such that the mask body is elastically deformed by a predetermined amount by tensioning the mask body by the frame by a thermal deformation at a usage temperature different from the predetermined temperature.

According to some embodiments of the present disclosure, the predetermined temperature is different from an ambient temperature.

According to some embodiments of the present disclosure, before fixing the mask body to the frame to form the mask in the case where the at least one of the mask body and the frame is at the predetermined temperature, the at least one of the mask body and the frame is heated or cooled to the predetermined temperature.

According to some embodiments of the present disclosure, the mask body has a rectangular shape, the frame has a rectangular ring shape, and the mask body is fixed at its four edges to the frame.

Embodiments of the present disclosure further provide a method of manufacturing a mask. The method comprises: controlling a temperature of a mask body and/or a temperature of a frame to reach a predetermined temperature, fixing the mask body to the frame, control the temperature of the mask body and the temperature of the frame to reach a usage temperature, and tensioning the mask body by the frame by a variation of the temperature of the mask body and/or a variation of the temperature of the frame, such that the mask body is elastically deformed by a predetermined amount.

In the embodiments of the present disclosure, a difference between the predetermined temperature of the mask body and/or the frame at which the mask body is fixed to the frame and the usage temperature of the mask at which the mask is used is adjusted by targeting the usage temperature of the mask body at which an evaporation is performed, for the mask body and frame of different materials and different coefficients of thermal expansion, and thus the mask body is fixed to the frame quickly in a case where there is a difference in size between the mask body and the frame. Therefore, in an actual usage state of evaporation, the frame will always tension the mask body in a plurality of directions for example two directions perpendicular to each other, and at the same time the amount of elastic deformation is accurately controllable. Therefore, the pixel position accuracy of the mask can be well controlled.

According to embodiments of the present disclosure, fixing the mask body to the frame to form the mask in the case where the at least one of the mask body and the frame is at the predetermined temperature, comprises: fixing the mask body to the frame in a case where the frame is at the predetermined temperature lower than the usage temperature and the mask body is at the usage temperature; fixing the mask body to the frame in a case where the frame is at the usage temperature and the mask body is at the predetermined temperature higher than the usage temperature; fixing the mask body to the frame in a case where the mask body and the frame are at the predetermined temperature lower than the usage temperature, such that the frame thermally expands more than the mask body at the usage temperature; or fixing the mask body to the frame in a case where the mask body and the frame are at the predetermined temperature higher than the usage temperature, such that the frame thermally contracts less than the mask body at the usage temperature.

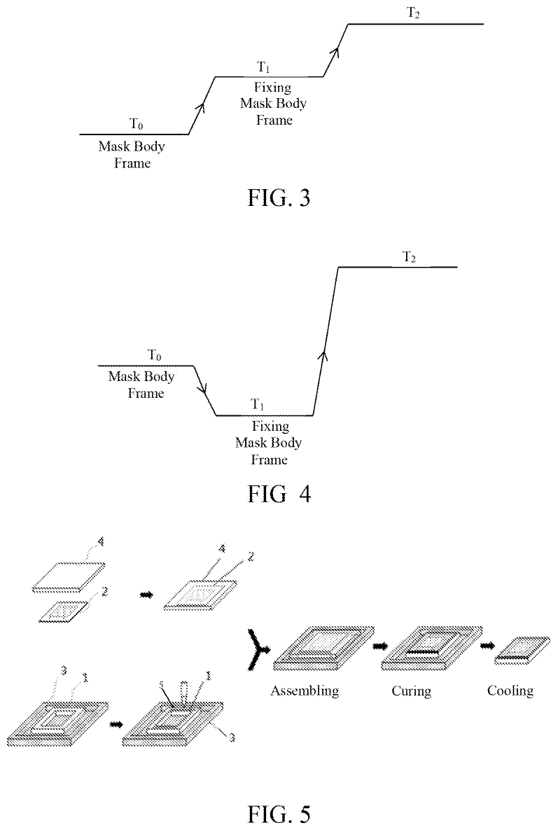

FIG. 3 is a schematic diagram showing a temperature change in a process of manufacturing a mask according to an example of the embodiment of the present disclosure; and FIG. 4 is a schematic diagram showing a temperature change in a process of manufacturing a mask according to another example of the embodiment of the present disclosure.

Referring to FIGS. 3 and 4, according to an embodiment of the present disclosure, there is provided a method of manufacturing a mask. The mask comprises a mask body and a frame. The mask body has a less coefficient of thermal expansion than the frame. The method comprises: providing a frame and a mask body; and fixing the mask body to the frame in a case where the mask body and the frame are at the predetermined temperature T₁, such that the frame thermally expands more than the mask body in a case where the mask is at the usage temperature T₂ and the usage temperature T₂ is greater than the predetermined temperature T₁, so that the mask body is elastically deformed by the predetermined amount by tensioning the mask body by the frame by the thermal deformation.

Referring to FIGS. 3 and 4, according to an embodiment of the present disclosure, there is further provided a method of manufacturing a mask. The mask comprises a mask body and a frame. The mask body has a less coefficient of thermal expansion than the frame. The method comprises the following steps.

As shown in FIG. 3, in a state where an ambient temperature is T₀, a temperature of the mask body and a temperature of the frame are controlled by heating to be a predetermined temperature T₁ greater than the ambient temperature T₀, and in this case the mask body is fixed to the frame. When an evaporation is performed with the mask body and the frame, the mask body and the frame absorb heat, and the temperature of the mask body and the temperature of the frame simultaneously rise to a usage temperature T₂ greater than the predetermined temperature T₁. Since the coefficient of thermal expansion of the mask body is less than the coefficient of thermal expansion of the frame, in this case, the frame expands more than the mask body, so that the mask body is elastically deformed by the predetermined amount by tensioning the mask body by the frame in a plurality of directions. The temperature T₂ is the final usage temperature of the mask. In other words, the temperature T₂ is a temperature of the mask body and the frame in a process of depositing a material from an evaporation source through the mask onto a thin film transistor (TFT) substrate in a vacuum evaporation environment.

In this embodiment, as shown in FIG. 4, it may also be selected in an implementation of the present disclosure to control, by cooling, a temperature of the mask body and a temperature of the frame to lower from the ambient temperature T₀ to the predetermined temperature T₁. In other words, the predetermined temperature T₁ is less than the ambient temperature T₀ In this case, the mask body is fixed to the frame. When an evaporation is performed with the mask body and the frame, the mask body and the frame absorb heat, and the temperature of the mask body and the temperature of the frame simultaneously rise to the usage temperature T₂ greater than the predetermined temperature T₁. In this case, the frame expands more than the mask body.

In the embodiments of the present disclosure, various temperatures of the mask body and the frame are based on the ambient temperature T₀. In a manufacturing process of fixing the mask body to the frame, regardless of how to adjust the temperatures of the mask body and the frame, the mask body is tensioned by the frame by targeting the usage temperature T₂ with the frame expanding more than the mask body as a criterion.

In the present embodiment, an accurate value of the predetermined amount by which the mask body is elastically deformed by tensioning the mask body by the frame by the thermal deformation can be obtained by a calculation. The predetermined amount by which the mask body is elastically deformed by tensioning the mask body by the frame by the thermal deformation is calculated by the following formula:

$${T}_{1} = {T}_{2} - \frac{{L}_{d} - {L}_{0}}{{L}_{0}} \times \frac{1}{{CTE}_{f} - {CTE}_{m}}$$

where T₁ is the predetermined temperature of the mask body and frame at which the mask body is fixed to the frame,

T₂ is the usage temperature of the mask body and the frame at which an evaporation is performed with the mask body and the frame,

L_{d} is a design size of the mask body (mm),

L₀ is an actual size of the mask body (mm),

CTE_{f} is the coefficient of thermal expansion of the frame (mm/mm·° C.)

CTEₘ is the coefficient of thermal expansion of the mask body (mm/mm·° C.), and
L_{d}−L₀ is the predetermined amount by which the mask body is elastically deformed by tensioning the mask body by the frame by the thermal deformation.

In the present embodiment, as an example, a material of the mask body is a glass, and a material of the frame is a stainless steel. The coefficient of thermal expansion CTEₘ of the mask body is equal to 3.5×10⁻⁶ mm/mm·° C., and the coefficient of thermal expansion CTE_{f} of the frame is equal to 15×10⁻⁶ mm/mm·° C. In this case, CTEₘ<CTE_{f}. The predetermined amount by which the mask body is elastically deformed by tensioning the mask body by the frame by the thermal deformation is calculated by the following formula:

$${T}_{1} = {T}_{2} - \frac{{L}_{d} - {L}_{0}}{{L}_{0}} \times \frac{1}{{CTE}_{f} - {CTE}_{m}}$$

Assuming that a rate of contraction of the mask body is determined as 0.02% in a design of the mask body, i.e. an actual size L₀ of the mask body is 99.98% of a design size L_{d} of the mask body, L₀=0.9998L_{d}. The data is substituted into the formula to obtain T₁=T₂−17.39° C. T₂ is the usage temperature of the mask body at which an evaporation is performed with the mask body. T₂ is a known quantity, and can be determined depending upon actual conditions. Herein, assuming T₂=40° C., it can be obtained that T₁=22.61° C. Therefore, the mask body is fixed to the frame at the temperature T₁ of 22.61° C. In other words, the temperatures of the mask body and the frame need to be firstly changed from the ambient temperature T₀ to 22.61° C. and then the mask body is fixed to the frame at this temperature.

The principle of the embodiments of the present disclosure is to fix the mask body to the frame by means of a difference in size between the mask body and the frame based on a difference in the amount of expansion or contraction between the mask body and the frame due to an influence of the temperature. Thereby, the mask body is tensioned by the frame in the plurality of directions and the positional accuracy of the mask body is controlled by the frame in the plurality of directions. In this way, the deviation of the pixel position of the mask body due to a rise in temperature during an evaporation can be eliminated. In the embodiments of the present disclosure, the mask body and the frame have different coefficients of thermal expansion because their materials are different from each other. When the temperature varies, the mask body and the frame have different amounts of expansion or contraction. A difference in size between the mask body and the frame is controlled by adjusting a difference between the predetermined temperature of the mask body and the frame at which the mask body is fixed to the frame and the usage temperature of the mask at which the mask is used, and then the mask body is fixed to the frame. When the temperatures of the mask body and the frame return to the usage temperature T₂, the frame will apply a predetermined tensile force to the mask body.

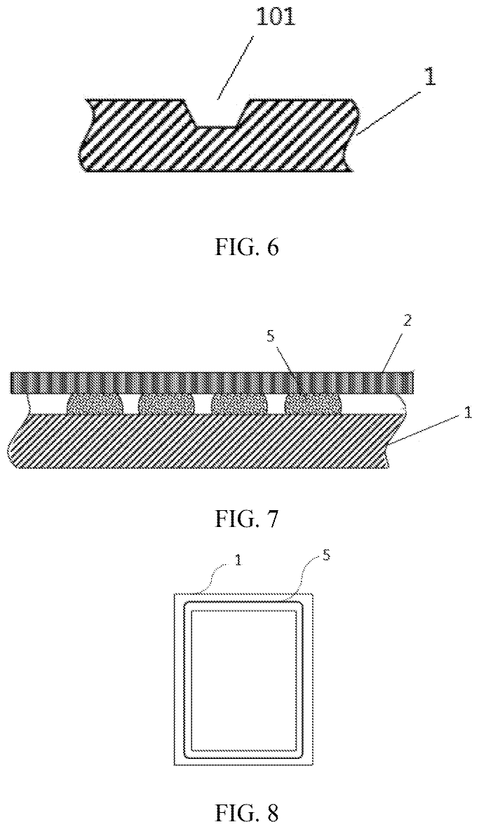

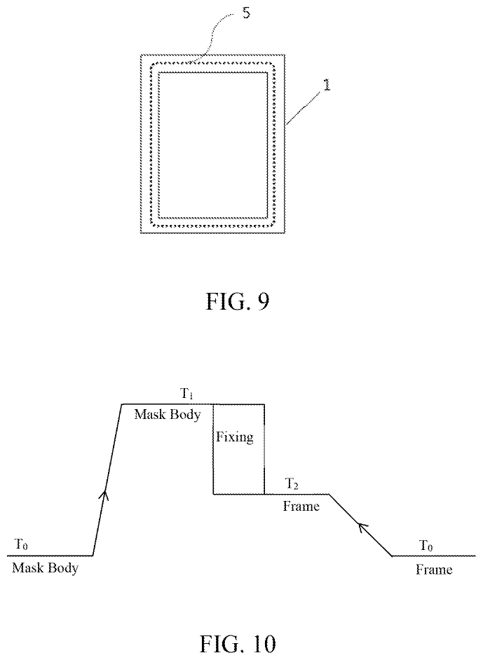

FIG. 5 is a schematic view showing components in steps in which a mask body is fixed to a frame, according to an embodiment of the present disclosure; FIG. 6 is a section view of the frame shown in FIG. 5 according to an embodiment of the present disclosure; FIG. 7 is a section view of the mask body and the frame, shown in FIG. 5, in a state where they are fixed together according to an embodiment of the present disclosure; FIG. 8 is a schematic view of the frame, shown in FIG. 5, to which an adhesive is applied according to an example of an embodiment of the present disclosure; and FIG. 9 is a schematic view of the frame, shown in FIG. 5, to which an adhesive is applied according to another example of the embodiment of the present disclosure.

In this embodiment, as shown in FIG. 5, a method of fixing the mask body to the frame comprises the following steps.

The frame 1 is placed in a temperature control platform 3 to control its temperature to be maintained at T₁, and a temperature control chuck 4 controls the temperature of the mask body 2 to be T₁ while sucking and flattening the mask body 2. Then, an adhesive 5 is applied to the frame 1, and the mask body 2 is placed on the frame 1 by means of the temperature control chuck 4 so that the mask body 2 and the frame 1 are assembled together, and the adhesive 5 is cured. Next, the mask body 2 and the frame 1 are cooled to the ambient temperature T₀. In use, the mask body 2 and the frame 1 are placed in a vacuum evaporation chamber. A material in an evaporation source evaporates upwards and is deposited onto a thin film transistor (TFT) substrate through the mask body. In this process, the temperatures of the mask body and the frame absorb heat so that their temperatures are changed to T₂. In this case, the mask body is tensioned by the frame in a plurality of directions to be deformed to the design size. In embodiments of the present disclosure, immediately after fixing the mask body 2 to the frame 1, a tensile force applied by the frame 1 to the mask body 2 is zero so that an amount by which the mask body 2 is elastically deformed by the frame 1 is zero. Likewise, before fixing the mask body 2 to the frame 1, the tensile force applied by the frame 1 to the mask body 2 is zero so that the amount by which the mask body 2 is elastically deformed by the frame 1 is zero. In other words, before and immediately after fixing the mask body 2 to the frame 1, the mask body 2 receives no tensile force applied by the frame 1 so that the amount by which the mask body 2 is elastically deformed by the frame 1 is zero. If the temperature of the mask body 2 and the temperature of the frame 1 retain unchanged when fixing the mask body 2 to the frame 1, the tensile force applied by the frame to the mask body is zero so that the amount by which the mask body is elastically deformed by the frame is zero. In the embodiments of the present disclosure, before and after fixing the mask body 2 to the frame 1, it is not necessary to utilize a method other than the thermal deformation to tension the mask body by the frame such that the mask body is elastically deformed by the predetermined amount.

It is necessary for the mask body 2 to form with pixel openings in an effective opening region and alignment marks outside the effective opening region simultaneously. In placing the mask body 2 onto the frame 1, it is only necessary to ensure that the effective opening region of the mask body 2 can appear in a hollowed area in a middle of the frame 1 without being blocked by the frame 1, so that a simple mechanical alignment is just required.

In some embodiments of the present disclosure, an ultraviolet ray (UV) curable adhesive is utilized, and the ultraviolet ray curable adhesive is cured by being irradiated with ultraviolet rays to fix the mask body 2 to the frame 1.

In some embodiments of the present disclosure, the method further comprises: before fixing the mask body to the frame to form the mask in the case where the at least one of the mask body and the frame is at the predetermined temperature, heating or cooling the at least one of the mask body and the frame to the predetermined temperature; applying an ultraviolet ray curable adhesive to the frame; and placing the mask body onto the frame to which the ultraviolet ray curable adhesive is applied. Fixing the mask body to the frame to form the mask in the case where the at least one of the mask body and the frame is at the predetermined temperature, comprises: curing the ultraviolet ray curable adhesive by irradiating the ultraviolet ray curable adhesive with ultraviolet rays to fix the mask body to the frame.

In this embodiment, as shown in FIGS. 6 and 7, a method of fixing the mask body 2 to the frame 1 by curing the adhesive 5 is as follows.

A groove 101 is formed on a surface of the frame 1. Then, the adhesive 5 is placed in the groove 101 such that an upper part of the adhesive 5 is protruded from an opening of the groove 101. Finally, the mask body 2 is placed onto the frame 1 and then the adhesive 5 is cured by being irradiated with ultraviolet rays, thereby completing an assembly.

In a conventional mask manufacturing method, whether a mask is a conventional etched metal mask or an electroformed metal mask, it is necessary to use laser welding to fix the mask body to a metal frame. However, the laser welding easily causes wrinkle and shrinkage at a welding point. In a case of a poor control, it is easy to cause an offset of a pixel position in the mask and reduce the accuracy. However, in the embodiments of the present disclosure, the mask body is fixed to the frame by curing the adhesive, which will not cause the problem of the offset of the pixel position.

In the embodiments of the present disclosure, a temperature control method is used to achieve a tension effect depending upon an amount of expansion of a material. In this method, precise control and maintenance of the temperature is the key. Otherwise it is difficult to achieve high precision of the mask. When the mask body is fixed to the frame in a case where they are at different temperatures, heat will transfers between the mask body and the frame after the mask body and the frame are brought into contact with each other, so that there is a deviation between an actual temperature and a theoretical value. The longer the time is, the greater the deviation of the temperature is, reducing the accuracy of the pixel position. Therefore, it is required to complete the fixation of the mask body to the frame in a very short time. For this reason, in embodiments of the present disclosure, an ultraviolet ray curable adhesive is utilized and the mask body is made of glass. The glass has good light transmittance, so that the mask body can be fixed to the frame within a few seconds, greatly reducing heat transfer between the mask body and the frame and thus ensuring accurate maintenance of the temperature.

In order to improve the reliability of curing the ultraviolet ray curable adhesive with ultraviolet rays, in the embodiments of the present disclosure, the frame is formed with the groove, which can ensure that the mask body is in good contact with the frame after applying the adhesive and the applied adhesive has a good flatness. The adhesive 5 may be applied to the frame 1 continuously in a ring as shown in FIG. 8. Alternatively, the adhesive 5 may be applied to the frame 1 discretely in a ring by intermittent dispensing as shown in FIG. 9. The intermittent dispensing has a better effect because there is a gap between the adhesives 5 after the intermittent dispensing. After the mask body is attached to the frame, the protruded part of the adhesive 5 will be pressed to both sides, thereby ensuring a good flatness of the adhesive without a situation where the adhesive 5 protrudes to push the mask body and the frame so that there is a gap between them.

In the manufacturing method according to the embodiment of the present disclosure, the mask body is elastically deformed by a predetermined amount by tensioning the mask body by the frame by a thermal deformation at an actual usage temperature of evaporation. Therefore, the deviation of the pixel position caused by the temperature rise of the mask during evaporation in the conventional method can be eliminated, the accuracy of the position of the pixel formed by depositing the material can be improved, and an occurrence of defects can be reduced.

In the embodiment of the present disclosure, both an accurate value of the predetermined amount by which the mask body is elastically deformed by tensioning the mask body by the frame by the thermal deformation, and an accurate value of the temperature at which the mask body is fixed to the frame can be obtained by a calculation. Thereby, the complicated conventional tensioning process and positional accuracy adjusting process are not needed in the process of manufacturing the mask, so that the process of manufacturing the mask is simple and efficient.

In the manufacturing method according to the embodiments of the present disclosure, the mask body is tensioned by expanding or contracting the frame by means of the difference between the predetermined temperature at which the mask body is fixed to the frame and the usage temperature at which the mask is used. The tension effect is not only more uniform, but also can achieve a tension effect in the X direction and the Y direction.

In the embodiments of the present disclosure, the materials for the mask body and frame are no longer limited to the conventional Invar in selection, but various materials can be selected, and according to the selection and collocation of different materials for the mask body and the frame, various corresponding fixing methods are provided, which has a great flexibility.

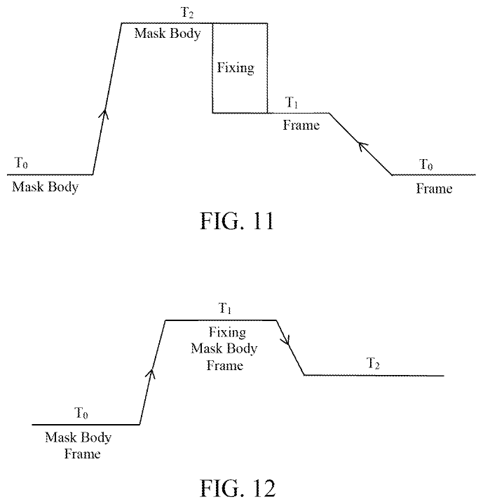

FIG. 10 is a schematic diagram showing a temperature change in a process of manufacturing a mask according to an example of a further embodiment of the present disclosure; and FIG. 11 is a schematic diagram showing a temperature change in a process of manufacturing a mask according to another example of the further embodiment of the present disclosure.

Referring to FIG. 10, according to an example of a further embodiment of the present disclosure, there is provided a method of manufacturing a mask. The mask comprises a mask body and a frame. The mask body has a same coefficient of thermal expansion as the frame. The method comprises: providing a frame and a mask body; and fixing the mask body to the frame in a case where the mask body is at the predetermined temperature T₁, the frame is at the usage temperature T₂, and the predetermined temperature T₁ is greater than the usage temperature T₂, such that the mask body contracts and the frame retains unchanged in size in a case where the mask is at the usage temperature T₂, so that the mask body is elastically deformed by the predetermined amount by tensioning the mask body by the frame by the thermal deformation.

Referring to FIG. 11, according to another example of the further embodiment of the present disclosure, there is provided a method of manufacturing a mask. The mask comprises a mask body and a frame. The mask body has a same coefficient of thermal expansion as the frame. The method comprises: providing a frame and a mask body; and fixing the mask body to the frame in a case where the mask body is at the usage temperature T₂, the frame is at the predetermined temperature T₁ and the usage temperature T₂ is greater than the predetermined temperature T₁, such that the mask body retains unchanged in size and the frame expands in a case where the mask is at the usage temperature T₂, so that the mask body is elastically deformed by the predetermined amount by tensioning the mask body by the frame by the thermal deformation.

Referring to FIGS. 10 and 11, according to another embodiment of the present disclosure, there is further provided a method of manufacturing a mask. The mask comprises a mask body and a frame. The mask body has a same coefficient of thermal expansion as the frame. The method comprises the following steps.

As shown in FIG. 10, in an example of the present embodiment, in a state where an ambient temperature is T₀, a temperature of the mask body is controlled to be a predetermined temperature T₁, a temperature of the frame is controlled to be a usage temperature T₂, and the predetermined temperature T₁ is greater than the usage temperature T₂, and in this case the mask body is fixed to the frame. When an evaporation is performed with the mask body and the frame, the temperature of the mask body and the temperature of the frame are controlled to reach the usage temperature T₂. In this case, the mask body is lowered in temperature to contract, while the frame is not changed in temperature so that the frame retains unchanged in shape and size. Thereby, the mask body is elastically deformed by the predetermined amount by tensioning the mask body by the frame in a plurality of directions. The temperature T₂ is the final usage temperature of the mask. In other words, the temperature T₂ is a temperature of the mask body and the frame in a process of depositing a material from an evaporation source through the mask onto a thin film transistor (TFT) substrate in a vacuum evaporation environment.

In the present embodiment, an accurate value of the predetermined amount by which the mask body is elastically deformed by tensioning the mask body by the frame by the thermal deformation can be obtained by a calculation. The predetermined amount by which the mask body is elastically deformed by tensioning the mask body by the frame by the thermal deformation is calculated by the following formula:

$${T}_{1} = {T}_{2} + \frac{{L}_{d} - {L}_{0}}{{L}_{0}} \times \frac{1}{{CTE}_{m}}$$

where T₁ is the predetermined temperature of the mask body at which the mask body is fixed to the frame,

T₂ is the usage temperature of the mask body and the frame at which an evaporation is performed with the mask body and the frame,

L_{d} is a design size of the mask body (mm),

L₀ is an actual size of the mask body (mm),

CTEₘ is the coefficient of thermal expansion of the mask body (mm/mm·° C.), and

L_{d}−L₀ is the predetermined amount by which the mask body is elastically deformed by tensioning the mask body by the frame by the thermal deformation.

In the present embodiment, as an example, each of a material of the mask body and a material of the frame is a glass. CTE_{f} is the coefficient of thermal expansion of the frame (mm/mm·° C.) CTEₘ is the coefficient of thermal expansion of the mask body, and CTEₘ=CTE_{f}=3.5×10⁻⁶ mm/mm·° C. The predetermined amount by which the mask body is elastically deformed by tensioning the mask body by the frame by the thermal deformation is calculated by the following formula:

$${T}_{1} = {T}_{2} + \frac{{L}_{d} - {L}_{0}}{{L}_{0}} \times \frac{1}{{CTE}_{m}}$$

Assuming that a rate of contraction of the mask body is determined as 0.02% in a design of the mask body, i.e. an actual size L₀ of the mask body is 99.98% of a design size L_{d} of the mask body, L₀=0.9998L_{d}. The data is substituted into the formula to obtain T₁=T₂+57.15° C. T₂ is the usage temperature of the mask body and the frame at which an evaporation is performed with the mask body and the frame. T₂ is a known quantity, and can be determined depending upon actual conditions. Herein, assuming T₂=40° C., it can be obtained that T₁=97.15° C. Therefore, during fixation for the mask, firstly, the temperature of the frame is raised to 40° C. while the temperature of the mask body is raised to 97.15° C., and an ultraviolet ray curable adhesive is applied to the frame. Then, after the mask body is attached to the frame, the ultraviolet ray curable adhesive is quickly cured by with ultraviolet rays.

In the embodiments of the present disclosure, the mask body is fixed to the frame by the ultraviolet ray curable adhesive. If the ultraviolet ray curable adhesive is used, the mask body is fixed to the frame rapidly. However, when the mask body is fixed to the frame in a case where they are at different temperatures, the mask body and the frame will still probably slightly fluctuate in temperature in a short time. In this case, an equivalent temperature compensation may be performed according to an actual quantity of the temperature fluctuation.

As shown in FIG. 11, in another example of the present embodiment, in a state where an ambient temperature is T₀, a temperature of the mask body is controlled to be a usage temperature T₂, a temperature of the frame is controlled to be a predetermined temperature T₁, and the usage temperature T₂ is greater than the predetermined temperature T₁, and in this case the mask body is fixed to the frame. When an evaporation is performed with the mask body and the frame, the temperature of the mask body and the temperature of the frame are controlled to reach the usage temperature T₂. In this case, the frame is raised in temperature to expand, while the mask body retains unchanged in temperature so that the mask body retains unchanged in shape and size. Thereby, the mask body is elastically deformed by a predetermined amount by tensioning the mask body by the frame by a thermal deformation. In addition, the mask body is tensioned by the frame in a plurality of directions. The temperature T₂ is the final usage temperature of the mask. In other words, the temperature T₂ is a temperature of the mask body and the frame in a process of depositing a material from an evaporation source through the mask onto a thin film transistor (TFT) substrate in a vacuum evaporation environment.

In the present embodiment, an accurate value of the predetermined amount by which the mask body is elastically deformed by tensioning the mask body by the frame by the thermal deformation can be obtained by a calculation. The predetermined amount by which the mask body is elastically deformed by tensioning the mask body by the frame by the thermal deformation is calculated by the following formula:

$${T}_{1} = {T}_{2} - \frac{{L}_{d} - {L}_{0}}{{L}_{0}} \times \frac{1}{{CTE}_{f}}$$

where T₁ is the predetermined temperature of the frame at which the mask body is fixed to the frame,

T₂ is the usage temperature of the mask body and the frame at which an evaporation is performed with the mask body and the frame,

L_{d} is a design size of the mask body (mm),

L₀ is an actual size of the mask body (mm),

CTE_{f} is the coefficient of thermal expansion of the frame (mm/mm·° C.), and

L_{d}−L₀ is the predetermined amount by which the mask body is elastically deformed by tensioning the mask body by the frame by the thermal deformation.

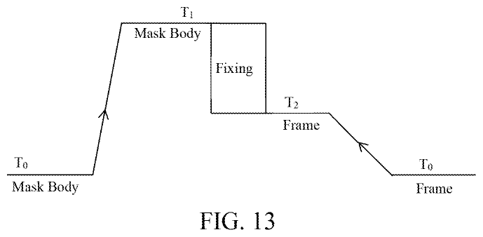

FIG. 12 is a schematic diagram showing a temperature change in a process of manufacturing a mask according to an example of a still further embodiment of the present disclosure; and FIG. 13 is a schematic diagram showing a temperature change in a process of manufacturing a mask according to another example of the still further embodiment of the present disclosure.

Referring to FIG. 12, according to an example of a still further embodiment of the present disclosure, there is provided a method of manufacturing a mask. The mask comprises a mask body and a frame. The mask body has a greater coefficient of thermal expansion than the frame. The method comprises: providing a frame and a mask body; and fixing the mask body to the frame in a case where the mask body and the frame are at the predetermined temperature T₁, such that the frame thermally contracts less than the mask body in a case where the mask is at the usage temperature T₂ and the usage temperature T₂ is less than the predetermined temperature T₁, so that the mask body is elastically deformed by the predetermined amount by tensioning the mask body by the frame by the thermal deformation.

Referring to FIG. 13, according to another example of the still further embodiment of the present disclosure, there is provided a method of manufacturing a mask. The mask comprises a mask body and a frame. The mask body has a greater coefficient of thermal expansion than the frame. The method comprises: providing a frame and a mask body; and fixing the mask body to the frame in a case where the frame is at the usage temperature T₂, the mask body is at the predetermined temperature T₁ and the usage temperature T₂ is less than the predetermined temperature T₁, such that the mask body contracts and the frame retains unchanged in size in a case where the mask is at the usage temperature T₂, so that the mask body is elastically deformed by the predetermined amount by tensioning the mask body by the frame by the thermal deformation.

Referring to FIG. 12, according to an example of a still further embodiment of the present disclosure, there is provided a method of manufacturing a mask. The mask comprises a mask body and a frame. The mask body has a greater coefficient of thermal expansion than the frame. As an example, a material of the mask body is a glass, and a material of the frame is invar. The method comprises the following steps.

As shown in FIG. 12, in a state where an ambient temperature is T₀, a temperature of the mask body and a temperature of the frame are controlled by heating to be a predetermined temperature T₁ greater than the predetermined temperature T₀, and in this case the mask body is fixed to the frame. When an evaporation is performed with the mask body and the frame, the temperature of the mask body and the temperature of the frame are controlled to be lowered to the usage temperature T₂ less than the predetermined temperature T₁. In this case, the mask body contracts more than the frame after being cooled, since the coefficient of thermal expansion of the mask body is greater than the coefficient of thermal expansion of the frame. Thereby, the mask body is elastically deformed by the predetermined amount by tensioning the mask body by the frame in a plurality of directions by a thermal deformation.

In the present embodiment, an accurate value of the predetermined amount by which the mask body is elastically deformed by tensioning the mask body by the frame by the thermal deformation can be obtained by a calculation. The predetermined amount by which the mask body is elastically deformed by tensioning the mask body by the frame by the thermal deformation is calculated by the following formula:

$${T}_{1} = {T}_{2} + \frac{{L}_{d} - {L}_{0}}{{L}_{0}} \times \frac{1}{{CTE}_{f} - {CTE}_{m}}$$

where T₁ is the predetermined temperature of the mask body and frame at which the mask body is fixed to the frame,

T₂ is the usage temperature of the mask body and the frame at which an evaporation is performed with the mask body and the frame,

L_{d} is a design size of the mask body (mm),

L₀ is an actual size of the mask body (mm),

CTE_{f} is the coefficient of thermal expansion of the frame (mm/mm·° C.)

CTEₘ is the coefficient of thermal expansion of the mask body (mm/mm·° C.), and

L_{d}−L₀ is the predetermined amount by which the mask body is elastically deformed by tensioning the mask body by the frame by the thermal deformation.

Referring to FIG. 13, according to another example of the still further embodiment of the present disclosure, there is provided a method of manufacturing a mask. The mask comprises a mask body and a frame. The mask body has a greater coefficient of thermal expansion than the frame. As an example, a material of the mask body is a glass, and a material of the frame is invar. The method comprises the following steps.

As shown in FIG. 13, in a state where an ambient temperature is T₀, a temperature of the frame is controlled to be a usage temperature T₂, a temperature of the mask body is controlled to be a predetermined temperature T₁, and the predetermined temperature T₁ is greater than the usage temperature T₂, and in this case the mask body is fixed to the frame. When an evaporation is performed with the mask body and the frame, the temperature of the mask body and the temperature of the frame are controlled to reach the usage temperature T₂. In this case, the frame retains unchanged in temperature with respect to the temperature of the fixation for the mask, so that the frame is not deformed, while the temperature of the mask body is lowered from the predetermined temperature T₁ to the usage temperature T₂, so that the mask body will contract. In this case, the mask body is elastically deformed by the predetermined amount by tensioning the mask body by the frame in a plurality of directions.

In the present embodiment, an accurate value of the predetermined amount by which the mask body is elastically deformed by tensioning the mask body by the frame by the thermal deformation can be obtained by a calculation. The predetermined amount by which the mask body is elastically deformed by tensioning the mask body by the frame by the thermal deformation is calculated by the following formula:

$${T}_{1} = {T}_{2} + \frac{{L}_{d} - {L}_{0}}{{L}_{0}} \times \frac{1}{{CTE}_{m}}$$

where T₁ is the predetermined temperature of the mask body at which the mask body is fixed to the frame,

T₂ is the usage temperature of the mask body and the frame at which an evaporation is performed with the mask body and the frame,

L_{d} is a design size of the mask body (mm),

L₀ is an actual size of the mask body (mm),

CTEₘ is the coefficient of thermal expansion of the mask body (mm/mm·° C.), and

L_{d}−L₀ is the predetermined amount by which the mask body is elastically deformed by tensioning the mask body by the frame by the thermal deformation.

Embodiments of the present disclosure further provide a mask manufactured by any one of the above methods. The mask comprises a frame and a mask body fixed to the frame. In the embodiments of the present disclosure, the materials of the mask body and frame are no longer limited to the conventional Invar, but various materials in a very wide range can be selected, and according to the selection and collocation of different materials of the mask body and the frame, different methods may be used in the embodiments of the present disclosure, which has a great flexibility.

In some embodiments of the present disclosure, a material of the mask body is a glass. The coefficient of thermal expansion of the mask body is 3˜4×10⁻⁶/° C. which is almost equal to a coefficient of thermal expansion of a thin film transistor (TFT) substrate of a glass. The coefficient of thermal expansion of the mask body is 3˜4×10⁻⁶/° C. which is nearly equal to a coefficient of thermal expansion of a thin film transistor (TFT) substrate of a glass. Further, there are many kinds of materials each having a less or greater coefficient of thermal expansion than the mask body of the glass. In the method according to the embodiments of the present disclosure, a frame of a material which has a coefficient of thermal expansion greater or less than, or equal to the coefficient of thermal expansion of the glass can be selected according to actual design requirements for the fixation and manufacturing, which greatly expands a range of usable materials of the frame.

Embodiments of the present disclosure further provide an evaporation method with a mask. The method comprises: providing a frame and a mask body; fixing the mask body to the frame to form the mask in a case where at least one of the mask body and the frame is at a predetermined temperature; and performing, with the formed mask, an evaporation at a usage temperature different from the predetermined temperature. The mask body is elastically deformed by a predetermined amount by tensioning the mask body by the frame by a thermal deformation.

According to some embodiments of the present disclosure, fixing the mask body to the frame to form the mask in the case where the at least one of the mask body and the frame is at the predetermined temperature, comprises: fixing the mask body to the frame in a case where the frame is at the predetermined temperature lower than the usage temperature and the mask body is at the usage temperature; fixing the mask body to the frame in a case where the frame is at the usage temperature and the mask body is at the predetermined temperature higher than the usage temperature; fixing the mask body to the frame in a case where the mask body and the frame are at the predetermined temperature lower than the usage temperature, such that the frame thermally expands more than the mask body at the usage temperature; or fixing the mask body to the frame in a case where the mask body and the frame are at the predetermined temperature higher than the usage temperature, such that the frame thermally contracts less than the mask body at the usage temperature.

According to embodiments of the present disclosure, fixing the mask body to the frame to form the mask in the case where the at least one of the mask body and the frame is at the predetermined temperature, may be performed by using various methods in the above embodiments.

Although some exemplary embodiments of the present disclosure have been shown above, it would be appreciated by a person skilled in the art that modifications may be made therein without departing from the principle and spirit of the present disclosure, the scope of which is defined in the appended claims and their equivalents.

1. A method of manufacturing a mask, the method comprising:
providing a frame and a mask body; and
fixing the mask body to the frame to form the mask in a case where at least one of the mask body and the frame is at a predetermined temperature, such that the mask body is elastically deformed by a predetermined amount by tensioning the mask body by the frame by a thermal deformation at a usage temperature different from the predetermined temperature.

2. The method of claim 1, wherein:
fixing the mask body to the frame to form the mask in the case where the at least one of the mask body and the frame is at the predetermined temperature, comprises:
fixing the mask body to the frame in a case where the frame is at the predetermined temperature lower than the usage temperature and the mask body is at the usage temperature;
fixing the mask body to the frame in a case where the frame is at the usage temperature and the mask body is at the predetermined temperature higher than the usage temperature;
fixing the mask body to the frame in a case where the mask body and the frame are at the predetermined temperature lower than the usage temperature, such that the frame thermally expands more than the mask body at the usage temperature; or
fixing the mask body to the frame in a case where the mask body and the frame are at the predetermined temperature higher than the usage temperature, such that the frame thermally contracts less than the mask body at the usage temperature.

3. The method of claim 1, wherein:
the usage temperature is a temperature of the mask at which an evaporation is performed with the mask.

4. The method of claim 1, wherein:
the mask body has a less coefficient of thermal expansion than the frame, and
fixing the mask body to the frame to form the mask in the case where the at least one of the mask body and the frame is at the predetermined temperature, comprises:
fixing the mask body to the frame in a case where the mask body and the frame are at the predetermined temperature T₁, such that the frame thermally expands more than the mask body in a case where the mask is at the usage temperature T₂ and the usage temperature T₂ is greater than the predetermined temperature T₁, so that the mask body is elastically deformed by the predetermined amount by tensioning the mask body by the frame by the thermal deformation.

5. The method of claim 4, wherein:
the predetermined amount by which the mask body is elastically deformed by tensioning the mask body by the frame by the thermal deformation is calculated by the following formula:
$${T}_{1} = {T}_{2} - \frac{{L}_{d} - {L}_{0}}{{L}_{0}} \times \frac{1}{{CTE}_{f} - {CTE}_{m}}$$
where T₁ is the predetermined temperature of the mask body and the frame at which the mask body is fixed to the frame,
T₂ is the usage temperature of the mask body and the frame at which an evaporation is performed with the mask body and the frame,
L_{d} is a design size of the mask body,
L₀ is an actual size of the mask body,
CTE_{f} is the coefficient of thermal expansion of the frame,
CTEₘ is the coefficient of thermal expansion of the mask body, and
L_{d}−L₀ is the predetermined amount by which the mask body is elastically deformed by tensioning the mask body by the frame by the thermal deformation.

6. The method of claim 1, wherein:
the mask body has a greater coefficient of thermal expansion than the frame, and
fixing the mask body to the frame to form the mask in the case where the at least one of the mask body and the frame is at the predetermined temperature, comprises:
fixing the mask body to the frame in a case where the mask body and the frame are at the predetermined temperature T₁, such that the frame thermally contracts less than the mask body in a case where the mask is at the usage temperature T₂ and the usage temperature T₂ is less than the predetermined temperature T₁, so that the mask body is elastically deformed by the predetermined amount by tensioning the mask body by the frame by the thermal deformation.

7. The method of claim 6, wherein:
the predetermined amount by which the mask body is elastically deformed by tensioning the mask body by the frame by the thermal deformation is calculated by the following formula:
$${T}_{1} = {T}_{2} + \frac{{L}_{d} - {L}_{0}}{{L}_{0}} \times \frac{1}{{CTE}_{f} - {CTE}_{m}}$$
where T₁ is the predetermined temperature of the mask body and frame at which the mask body is fixed to the frame,
T₂ is the usage temperature of the mask body and the frame at which an evaporation is performed with the mask body and the frame,
L_{d} is a design size of the mask body,
L₀ is an actual size of the mask body,
CTE_{f} is the coefficient of thermal expansion of the frame,
CTEₘ is the coefficient of thermal expansion of the mask body, and
L_{d}−L₀ is the predetermined amount by which the mask body is elastically deformed by tensioning the mask body by the frame by the thermal deformation.

8. The method of claim 1, wherein:
the mask body has a greater coefficient of thermal expansion than the frame, and
fixing the mask body to the frame to form the mask in the case where the at least one of the mask body and the frame is at the predetermined temperature, comprises:
fixing the mask body to the frame in a case where the frame is at the usage temperature T₂, the mask body is at the predetermined temperature T₁ and the usage temperature T₂ is less than the predetermined temperature T₁, such that the mask body contracts and the frame retains unchanged in size in a case where the mask is at the usage temperature T₂, so that the mask body is elastically deformed by the predetermined amount by tensioning the mask body by the frame by the thermal deformation.

9. The method of claim 1, wherein:
the mask body has a same coefficient of thermal expansion as the frame, and
fixing the mask body to the frame to form the mask in the case where the at least one of the mask body and the frame is at the predetermined temperature, comprises:
fixing the mask body to the frame in a case where the mask body is at the predetermined temperature T₁, the frame is at the usage temperature T₂, and the predetermined temperature T₁ is greater than the usage temperature T₂, such that the mask body contracts and the frame retains unchanged in size in a case where the mask is at the usage temperature T₂, so that the mask body is elastically deformed by the predetermined amount by tensioning the mask body by the frame by the thermal deformation.

10. The method of claim 8, wherein:
the predetermined amount by which the mask body is elastically deformed by tensioning the mask body by the frame by the thermal deformation is calculated by the following formula:
$${T}_{1} = {T}_{2} + \frac{{L}_{d} - {L}_{0}}{{L}_{0}} \times \frac{1}{{CTE}_{m}}$$
where T₁ is the predetermined temperature of the mask body at which the mask body is fixed to the frame,
T₂ is the usage temperature of the mask body and the frame at which an evaporation is performed with the mask body and the frame,
L_{d} is a design size of the mask body,
L₀ is an actual size of the mask body,
CTEₘ is the coefficient of thermal expansion of the mask body, and
L_{d}−L₀ is the predetermined amount by which the mask body is elastically deformed by tensioning the mask body by the frame by the thermal deformation.

11. The method of claim 1, further comprising:
before fixing the mask body to the frame to form the mask in the case where the at least one of the mask body and the frame is at the predetermined temperature, heating or cooling the at least one of the mask body and the frame to the predetermined temperature; applying an ultraviolet ray curable adhesive to the frame; and placing the mask body onto the frame to which the ultraviolet ray curable adhesive is applied,
wherein fixing the mask body to the frame to form the mask in the case where the at least one of the mask body and the frame is at the predetermined temperature, comprises:
curing the ultraviolet ray curable adhesive by irradiating the ultraviolet ray curable adhesive with ultraviolet rays to fix the mask body to the frame.

12. The method of claim 1, wherein:
the predetermined temperature is different from an ambient temperature.

13. The method of claim 12, further comprising:
before fixing the mask body to the frame to form the mask in the case where the at least one of the mask body and the frame is at the predetermined temperature, heating or cooling the at least one of the mask body and the frame to the predetermined temperature.

14. The method of claim 1, wherein:
the mask body has a rectangular shape, the frame has a rectangular ring shape, and the mask body is fixed at its four edges to the frame.

15. The method of claim 1, wherein:
the mask body has a same coefficient of thermal expansion as the frame, and
fixing the mask body to the frame to form the mask in the case where the at least one of the mask body and the frame is at the predetermined temperature, comprises:
fixing the mask body to the frame in a case where the mask body is at the usage temperature T₂, the frame is at the predetermined temperature T₁ and the usage temperature T₂ is greater than the predetermined temperature T₁, such that the mask body retains unchanged in size and the frame expands in a case where the mask is at the usage temperature T₂, so that the mask body is elastically deformed by the predetermined amount by tensioning the mask body by the frame by the thermal deformation.

16. The method of claim 15, wherein:
the predetermined amount by which the mask body is elastically deformed by tensioning the mask body by the frame by the thermal deformation is calculated by the following formula:
$${T}_{1} = {T}_{2} - \frac{{L}_{d} - {L}_{0}}{{L}_{0}} \times \frac{1}{{CTE}_{f}}$$
where T₁ is the predetermined temperature of the frame at which the mask body is fixed to the frame,
T₂ is the usage temperature of the mask body and the frame at which an evaporation is performed with the mask body and the frame,
L_{d} is a design size of the mask body,
L₀ is an actual size of the mask body,
CTE_{f} is the coefficient of thermal expansion of the frame, and
L_{d}−L₀ is the predetermined amount by which the mask body is elastically deformed by tensioning the mask body by the frame by the thermal deformation.

17. The method of claim 1, wherein:
immediately after fixing the mask body to the frame, a tensile force applied by the frame to the mask body is zero so that an amount by which the mask body is elastically deformed by the frame is zero.

18. A mask manufactured by the method of claim 1, the mask comprising a frame and a mask body fixed to the frame.

19. The mask of claim 18, wherein:
a material of the mask body is a glass.

20. An evaporation method with a mask, the method comprising:
providing a frame and a mask body;
fixing the mask body to the frame to form the mask in a case where at least one of the mask body and the frame is at a predetermined temperature; and
performing, with the formed mask, an evaporation at a usage temperature different from the predetermined temperature, such that the mask body is elastically deformed by a predetermined amount by tensioning the mask body by the frame by a thermal deformation.

21. (canceled)
